(19) United States
(12) Patent Application Publication
(10) Pub. No.: US 2009/0178933 A1
(43) Pub. Date: Jul. 16, 2009

(54) Method for Making Nanoparticles or Fine Particles

(76) Inventor: Taofang Zeng, Cambridge, MA (US)

Correspondence Address: SQUIRE, SANDERS & DEMPSEY L.L.P., 1 MARITIME PLAZA, SUITE 300, SAN FRANCISCO, CA, 94111, US

(21) Appl. No.: 12/353,912

(22) Filed: Jan. 14, 2009

Related U.S. Application Data
(60) Provisional application No. 61/011,039, filed on Jan. 14, 2008.

(51) Int. Cl. C30B 30/06; B29B 9/00

(52) U.S. Cl. 205/766; 264/9

(57) ABSTRACT

A method for making nanoparticles or fine particles includes (1) in an electrolysis cell, supplying a power (potentiostat) to an element that acts as a counter electrode, and another element that is working electrode; and rubbing the working electrode to make nanoparticles or fine particles. Another method for making nanoparticles or fine particles includes (1) in an electrolysis cell, supplying a power (potentiostat) to an element that acts as a counter electrode, and another element that is working electrode; and (2) mechanically vibrating the working electrode to make nanoparticles or fine particles.

### CROSS-REFERENCE TO RELATED APPLICATIONS

The present application claims the benefit of the provisional patent application filed on Jan. 14, 2008, and assigned application No. 61/011,039, and is incorporated by reference herein in its entirety.

### TECHNICAL FIELD OF THE INVENTION

The present invention relates to a method for making nanoparticles or fine particles.

### BACKGROUND OF THE INVENTION

Nanoparticles or fine particles are basic building blocks for nanotechnology. They have been widely exploited for application in photography, catalysis, biological labeling, photonics, optoelectronics, information storage, solar cells, and formulation of magnetic ferrofluids. The physical and chemical properties of a metal nanoparticle are mainly determined by its size, shape, composition, crystallinity, and structure (solid versus hollow). In principle, one could change any one of these parameters to tune the properties of the nanoparticle. Among them, control over these parameters is crucial for a successful utilization of the size-dependent properties that are unique to nanoparticles or fine particles, and is particularly important in assembly of monolayer protected nanoparticles or fine particles into crystalline arrays of one-, two- or three-dimensions.

Nanoparticles or fine particles, metal nanoparticles or fine particles, for instance, have been prepared by a wide variety of techniques such as laser ablation, deposition by plasma, nucleation from vapor, microwave-assisted hydrothermal synthesis, thermal decomposition of organometallic compounds, sonolysis, pulse radiolysis, electrochemical reduction (electrolysis), and chemical reduction of the corresponding metal salts. Reduction of metal salts in the presence of a suitable protecting agent is one of the most commonly used techniques. Generally, a reducing reagent, such as borohydride, hydrotriorganoborates, hydrogen or citrate, is added to a solution of the corresponding metal salt. An easily oxidized solvent may function both as the electron donor and the dispersing medium. Alcohols and ethers have been quite extensively used for this purpose. A recent book edited by Schmid [Schmid, G. (Ed.), 2004, Nanoparticles: From Theory to Applications, WILEY-VCH, Weinheim, Germany] summarizes contemporary synthesis methods.

Inexpensive, large-scale, (size and shape) controllable and environment-benign synthesis is the goal of all synthesis methods. Unfortunately, none synthesis method can achieve all these goals simultaneously. The physical methods including laser ablation and plasma etching can produce almost all kinds of metal nanoparticles or fine particles, but precise size control is difficult. Additionally, the manufacturing process has to be performed in vacuum, which is expensive. Chemical methods could be inexpensive. However, almost all of them have to be performed in reducing agents that are highly reactive and pose potential environmental and biological risks. Some chemical methods require precursors that are expensive to make. An example is making iron nanoparticles or fine particles from iron carbonyl.

Another chemical method for nanoparticle synthesis is electrochemical reduction (e.g. M. T. Reetz, W. Helbig, Journal of the American Chemical Society, vol. 116, p. 7401, 1994). Two electrodes and an electrolyte consist of the synthesis system. The synthesis system is simple and the synthesis process is straightforward. However, the synthesis has to use an electrolyte made of selective or special surfactants that can stabilize and/or protect the reduced the atoms at the cathode, meanwhile the electrolyte should be able to conduct electrons in the solution. The overall reaction is thus controlled by these special electrolytes, and is very slow.

A similar method for nanoparticle synthesis is electrocoagulation (e.g. U.S. Pat. No. 6,179,987 issued in 2001), which uses a synthesis system similar to the above electrochemical reduction, yet with a different electrolyte. Again, the overall reaction or the nanoparticle production rate is also decided by the electrolyte, and is low. Another similar method is sonoelectrochemistry synthesis proposed by Reisse and co-workers (J. Reisse, H. Francois, J. Vandjzrcammen, et al., Electrochimica Acta, vol. 39, pp. 37-39, 1994). Metallic cations in the electrolyte are reduced to metal atoms by applied electricity at the cathode, working electrode that is made up of the immersed titanium horn. The reduced atoms then form nanoparticles in the electrolyte. The method is, however, slow and cannot be scaled-up for commercialization (Y. Kehelaers, J.-C. Delpllancke, J. Reisse, Chimia, vol. 54, pp. 48-50, 2000). Detailed comparison will be made in the Section of Detail Description.

A need exists for finding better, more efficient, more versatile methods for scale up for mass production of broad nanoparticles or fine particles with inexpensive process.

### SUMMARY OF THE INVENTION

In light of the foregoing and other problems of the conventional methods and processes, an objective of the present invention is to provide an inexpensive chemical method for preparing stable elemental, alloy, intermetallic, conducting or semi-conducting, conducting-polymeric, and over-coated nanoparticles or fine particles in mass production.

Metal electrolysis is used as an example for elucidating the invention principles, while the invention should not be limited to metals. Based on the basic electrochemical principle that a metal is electrolyzed at the anode and is reduced to a corresponding metal atom at the cathode, we bring forward a new synthesis to make use of the electrochemical reduction (electrolysis). In typical electrolysis,

At the anode: M_{bulk}→Mⁿ⁺+ne⁻

At the cathode: Mⁿ⁺+ne⁻→Mₐₜₒₘ

Where, M_{bulk} is bulk material that is can be electrolyzed; Mⁿ⁺ is cations, e⁻ is electron, n is the ionic valence, and Mₐₜₒₘ is the atom reduced from the cations Mⁿ⁻. If one can make a condition such that the precursors, Mₐₜₒₘ, interact with each other and grow, nanoparticles or fine particles of M element formalize.

However, in general electrolysis, due to inter-molecular forces, the reduced atoms, M, have a tendency to accumulate on the cathode, leading to plating and bulk formation. Electroplating based on electrolysis is an industrial process. To prevent deposition of the reduced atoms onto the cathode, researchers have used surfactants or stabilizer in the electrolytes. Yet, only a low electric current was or could be applied onto the electrodes such that the all the reduced atoms can be protected by the surfactants and do not deposit on the cathode.

In the present invention, mechanical methods are used to prevent deposition of precursors onto the working electrode. In the first aspect of the invention, we employ a rubbing member, such as a polishing pad or a “scrubbing” brush or pad, in contact with a moving working electrode, which immediately removes reduced newborn atoms/molecules or atomic/molecular clusters from the working electrode. A counter electrode can be made from any suitable material such as a noble metal. The method is derived from chemical-mechanical planarization. Alternatively, the rubbing member may be moving while the working electrode remains stationary, or both are in motion. In the method, turbulent agitation resulting from the moving cathode or the rubbing member in the solution further helps eject the atomistic species from the cathode, transferring them into the bulk phase and creating a uniform suspension. The mechanical and hydrodynamic forces effectively prevent plating and bulk formation and distribute particles evenly in solution or electrolyte providing more homogeneous particle nucleation and growth.

In the second aspect of the present invention, vibration is applied to the working electrode to shake the reduced newborn atoms/molecules or atomic/molecular clusters from the cathode surface. Preferably, no nano-cluster or no plating at all is formed on the working electrode. The vibration can be generated from any vibration sources. A preferred setup for vibration is from the piezoelectric effect: A piezoelectric element transduces modulated power to vibration. Then the vibration is transferred to the working electrode attached to the piezoelectric element. More preferably, the vibration frequency produced from the piezoelectric effect is the same or close to the resonant frequency of the working electrode. Under this condition, the vibration has the highest intensity with a given power input.

According to one aspect of the invention, a method for making nanoparticles or fine particles includes (1) in an electrolysis cell, supplying a power (potentiostat) to a counter electrode and a working electrode; and (2) rubbing the working electrode to make nanoparticles or fine particles. The method may further include the previous steps with a different material element to make core-shell like structured nanoparticles or fine particles.

In this method, the step of rubbing the working electrode may include rubbing a rubbing member against the working electrode, wherein at least one of the rubbing member and the working electrode is moving. The rubbing member may be hairy and/or may be solid. The electrolysis cell preferably contains two or more metallic components acting as anode to make intermetallic nanoparticles or fine particles. The method may further include adding a gas to the electrolyte solution to make nanoparticles or fine particles. The nanoparticles or fine particles may be oxide nanoparticles or fine particles. The gas may be oxygen. The method may further include adding a surfactant to the electrolyte. The surfactant is poly(vinylpyrrolidone) (PVP), or tetraoctylammoniumbromide (TOAB), or cetyltrimethylammonium bromide (CTAB). The counter electrode may be a noble metal. The method may further include adding an antioxidant to the electrolyte. The antioxidant is ascorbic acid. The electrolyte may be a mixture solution containing two or more kinds of cations with elements required to form semiconductor compounds. The mixture solution may be a CdSO₄/Na₂SeO₃ mixture solution, and an electrochemically inert material such as Pt acting may act as a counter electrode. The method electrolyte may be a mixture solution containing a precursor monomer and a supporting electrolyte for making conducting nanoparticles or fine particles. The mixture solution may be a pyrrole/NaClO₄ mixture solution, and an electrochemically inert material such as Pt may act as a counter electrode.

According to another aspect of the invention, a method for making nanoparticles or fine particles include (1) in an electrolysis cell, supplying a power (potentiostat) to a counter electrode and a working electrode; and (2) mechanically vibrating the working electrode to make nanoparticles or fine particles. The method may further include the previous steps with a different material element to make core-shell like structured nanoparticles or fine particles.

In this method, the step of vibrating the working electrode may include vibrating the working electrode. The vibration may be produced by a piezoeletrics. The working electrode preferably has a solid or shell structure with a cylindrical or conic geometry. The electrolysis cell may contain two or more metallic components acting as anode to make intermetallic nanoparticles or fine particles. The method may further include adding a gas to the electrolyte solution to make nanoparticles or fine particles. The nanoparticles or fine particles may be oxide nanoparticles or fine particles. The gas may be oxygen. The method may further include adding a surfactant to the electrolyte. The surfactant is poly(vinylpyrrolidone) (PVP), or tetraoctylammoniumbromide (TOAB), or cetyltrimethylammonium bromide (CTAB). The counter electrode may be a noble metal. The method may further include adding an antioxidant to the electrolyte. The antioxidant may be ascorbic acid. The electrolyte may be a mixture solution containing two or more kinds of cations with elements required to form semiconductor compounds. The mixture solution may be a CdSO₄/Na₂SeO₃ mixture solution, and an electrochemically inert material such as Pt acting may act as a counter electrode. The method electrolyte may be a mixture solution containing a precursor monomer and a supporting electrolyte for making conducting nanoparticles or fine particles. The mixture solution may be a pyrrole/NaClO₄ mixture solution, and an electrochemically inert material such as Pt may act as a counter electrode.

### BRIEF DESCRIPTION OF THE DRAWING

The foregoing and other purposes, aspects and advantages, as well as synthesis approaches and characterized results of the present invention, will be better understood from the following detailed description of some preferred embodiments of the invention with reference to the drawings, in which:

FIG. 1 shows the schematic setup of the rubbing method for the synthesis of metallic nanoparticles or fine particles by electrolysis.

FIG. 2 shows the schematic setup of another rubbing method for the synthesis of metallic nanoparticles or fine particles by electrolysis.

FIG. 3 shows the schematic setup of the vibration method for the synthesis of metallic nanoparticles or fine particles by electrolysis.

FIG. 4 shows TEM images of Cu nanoparticles or fine particles synthesized with sonication under the following conditions: 100 g of CuSO₄.5H₂O, 400 ml of H₂O, 1.5 g of poly(vinylpyrrolidone) (PVP), 1.3-1.7 Volts of Voltage, 1.5 A of Current, 60 minutes of electrolysis Time.

FIG. 5 shows TEM images of Cu nanoparticles or fine particles synthesized with sonication under the following conditions: 100 g of CuSO₄.5H₂O, 400 ml of H₂O, 1.0-1.2 Volts of Voltage, 1-1.2 A of Current, 40 minutes of Time.

FIG. 6 shows TEM images of Fe nanoparticles or fine particles synthesized with sonication under the following conditions: 137 g of FeSO₄.7H₂O, 300 ml of H₂O, 34 g of Ascorbic Acid, 1.0 Volt of Voltage, 0.2 A of Current, 60 minutes of Time.

### DETAILED DESCRIPTION OF PREFERRED EMBODIMENTS OF THE INVENTION

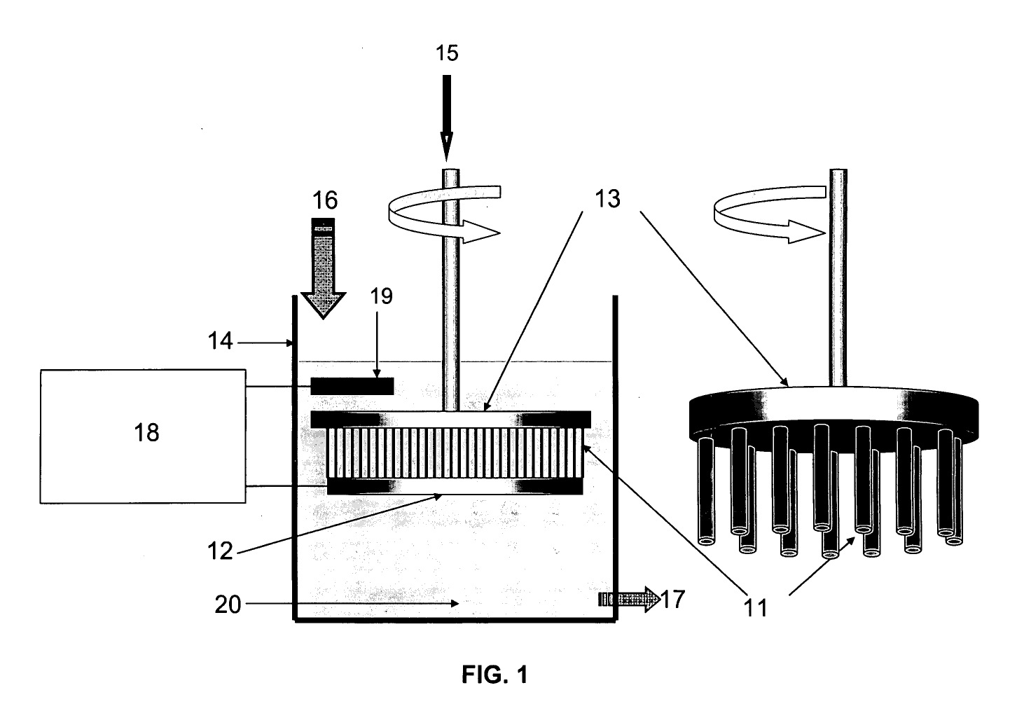

Referring to the drawings and more particularly to FIGS. 1-6, embodiments of the invention are illustrated as followed.

The present invention may be an economic and scalable process for preparing monodisperse nanoparticles or fine particles of metals, metallic alloys, metal oxides, semiconductors, conducting polymers, and core-shell structures in three different methods. As illustrated below, high-quality nanoparticles or fine particles of Cu, Fe are synthesized by the method.

The method is based on the electrochemical reduction of precursor cations or polymerization at the anode with the aid of de-plating and mass transport resulting from mechanical forces. The invention allows simple and green synthesis and continuous production. Size selectivity and size distribution control can be realized in a straightforward manner by adjusting reactant concentration, the current density, and particle average residence time in the continuous flow system.

The first part of the present invention is electrochemical-mechanical nanoparticles or fine particles synthesis strategy or mechanically assisted electrolysis in a continuous and steady-flow reaction system, or in a batch system. The universal electrolysis principle states that a cation or cation complex can be reduced to corresponding atomic state in solution on the electric cathode. We, in the first instance, exploit electrolysis and therefrom mechanical rubbing as a new approach for nanoparticles or fine particles generation. Take metal (M) electrolysis as an example, the electrolyzed cation M⁺ is reduced to atom M at the cathode. The atoms M or nano-cluster of atoms M can be removed from the surface of the cathode by using a mechanical force. These atoms or nano-cluster are dispersed in solution phase. They then grow into nanosize particles, with or without the presence of capping agent through a series of nucleation and kinetic coagulation processes.

In traditional heterogeneous-phase reduction, metal ions in solution are reduced on the cathode surface. Due to inter-molecular forces, the reduced atoms and resulting nuclei and particles have a tendency to accumulate on the surface of the working electrode, leading to plating and bulk formation. This is electroplating, which is widely used in industry to refine metals or electroplate protective metals.

In the present invention, we engineered a method to overcome deposition, which is inspired by chemical-mechanical planarization (CMP). As illustrated in FIG. 1, we employ a “scrubbing” brush 11 functioning like a “polishing” pad in constant contact with the rotating working electrode 12. This soft and hairy brush 11 (can be solid hard brush as well, an example is a brush purchased from Wal-Mart for household use) immediately removes newborn atoms/molecules or atomic/molecular clusters from the foil surface during the reduction process. Preferably, the rotating metal plate has a high rotation velocity (e.g. more than 1000 rpm) to prevent any possible electroplating. The brush 11 is held by a holder 13, and is fixed or is placed loosely in a container or reactor 14. The working electrode 12 makes constant contact with the brush 11 under an applied load 15. The solution of reactant 16 can be constantly supplied to the reactor 14, and the product 17 that contains nanoparticles or fine particles is constantly collected. A power supply (potentiostat) 18 is applied between the working electrode 12 and the counter electrode 19, both immersed in electrolyte 20. In addition, turbulent agitation resulting from high-speed rotation of a substrate disk and attached foil in the solution further helps ejecting the particle species from the foil, transferring them into the bulk phase and creating a well-mixed, uniform suspension.

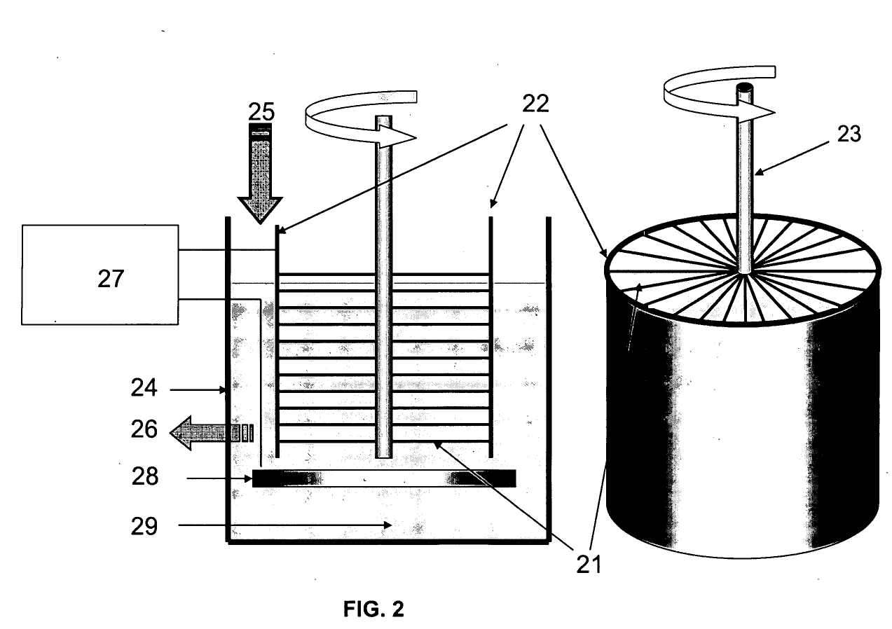

FIG. 2 schematically shows another setup for mechanically assisted electrolysis synthesis. In the system, the rotating “scrubbing” brush 21 is a cylindrical “polishing” pad in constant contact with a rotating or still metal foil or metal plate (working electrode) 22. This soft and hairy cylindrical brush 21 (can be solid hard brush as well, a special designed one) immediately removes newborn atoms or atom clusters from the foil surface during the reduction process. Preferably, the rotating polishing pad or the metal plate has a high rotation velocity (e.g. more than 1000 rpm) to prevent any possible electroplating. The brush 21 is held by a holder 23, and is fixed or is placed loosely in a container or reactor 24. The metal plate 22 (or generally a metal element) makes constant contact with the brush 21. The solution of reactant 25 can be constantly supplied to the reactor 24, and the product 26 that contains nanoparticles or fine particles is constantly collected. In addition, turbulent agitation resulting from high-speed rotation of a substrate disk and attached foil in the solution further helps ejecting the particle species from the foil, transferring them into the bulk phase and creating a well-mixed, uniform suspension. A power supply (potentiostat) 27 is applied between the working electrode 22 and the counter electrode 28, both immersed in electrolyte 29.

In hydrodynamically and mechanically assisted metal displacement reduction, the mechanical and hydrodynamic forces not only effectively prevent plating and bulk formation by the scrubbing action but also facilitate mass transport and well-mixing, providing more favorable conditions for particle nucleation and growth. Our method in continuous flow also circumvents the intrinsic drawback in the microfluidic reactors-reactor fouling, which is due to the aggregates' settling on the inner surface of the tube wall. For desired size and size distribution, the synthesis is performed similarly to industrial MSMPR (mixed suspension, mixed product removal) crystallizers. The continuous and steady-state operating MSMPR vessel, characterized by a feeding stream of precursor ionic solution and an exit stream of mixed reaction solution, allows regulated control of average residence time of suspended nanoparticles or fine particles, providing particles with selective growth time and size tunability.

To offset progressive nucleation and realize better size and distribution variation, preferably, the present invention employs a continuous flow reaction system rather than the typical batch system. A typical reaction system includes a rotating metal element such as a rotating plate with metal foil immersed in an electrolyte solution. The working electrode is scrubbed by a rubbing member such as a soft pad or brush. A solution with same ions is supplied continuously to the reactor, and the same amount of liquid loaded with particles flows out of the reactor. The continuous steady-state vessel, characterized by a feeding stream and an exit stream, allows regulated control of average residence time of the produced nanoparticles or fine particles, providing particles of selected size and distribution. Furthermore, the externally applied voltage can be adjusted to achieve the potential difference for the desired particle size and dispersity, thus providing broader opportunities in size tuning.

Preferably, with the present invention, the nanoparticles or fine particles are protected from oxidation by using an anti-oxidant such as vitamin C during formation of metal nanoparticles or fine particles.

After obtaining nanoparticles or fine particles in a reactor, the nanoparticles or fine particles can serve as the seed particles, over which an outer layer may be deposited by another material to form core-shell structure. For example, one can put the formed gold nanoparticles or fine particles into an electrolysis reactor with silver nitrate. By electrolysing silver, the reduced silver atoms could deposit onto the gold nanoparticles or fine particles, so an Au—Ag core-shell structure can be formed. Another example is depositing a silver layer onto copper nanoparticles or fine particles: first, copper nanoparticles or fine particles are formed by electrolysis with mechanical rubbing; the Cu nanoparticles or fine particles are then put into a reactor containing silver nitrate. Copper reacts with silver nitrate, and the reduced silver atoms deposit onto the copper particle. Meanwhile copper atoms could diffuse outward. In general, a Cu—Ag alloy layer could be formed as a surface layer. By controlling the reaction time and/or the concentration of silver nitrate, a structure of Cu core and Cu(x)Ag(1−x) shell could be produced. Here x represents the fraction of copper. Preferably, x equals to 0, or an Ag shell is desired.

One could also put two metals in an electrolysis cell to make intermetallic (alloy) nanoparticles or fine particles. An example is electrolysing Au and Ag in a cell. The co-deposition of Au and Ag in the electrolysis cell could form Au—Ag nanoparticles or fine particles.

If one supplies a gas that reacts with the particles into the electrolyte while the nanoparticles or fine particles are produced, another type of nanoparticles or fine particles could be produced. For example, when oxygen is bubbled into the electrolysis cell for Cu, the formed Cu atoms or nano-clusters in the electrolyte could be oxidized so copper oxide nanoparticles or fine particles could be produced.

For producing alloy nanoparticles or fine particles, a potential may be applied between the cathode and the counter electrode (anode). The electrolyte may be a mixture solution containing two or more kinds of metallic cations. For example, in a typical electrochemical experiment for synthesis of Cu/Zn alloy nanoparticles or fine particles, the CuSO₄/ZnSO₄ mixture solution may act as the electrolyte and the bulk Cu/Zn alloy may act as the counter electrode.

For the synthesis of semiconductor nanoparticles or fine particles, the electrolyte may be a mixture solution containing two or more kinds of cations with elements required to form semiconductor compounds. In a typical synthesis of CdSe semiconductor nanoparticles or fine particles, the CdSO₄/Na₂SeO₃ mixture solution may act as the electrolyte and some electrochemically inert material such as Pt acted as the counter electrode (anode).

For the synthesis of conducting polymer nanoparticles or fine particles, the electrolyte may be a mixture solution containing the precursor monomer and the supporting electrolyte. In this case, the working electrode shall be the anode and the cathode shall be the counter electrode. The anode shall be used to induce the polymerization. For example, in a synthesis of polypyrrole nanoparticles or fine particles, the pyrrole/NaClO₄ mixture solution may act as the electrolyte and some electrochemically inert material such as Pt acted as the counter electrode.

The second part of the present invention is electrochemical reduction assisted by mechanical vibration in a continuous and steady-flow reaction system, or in a batch system. In the synthesis, the produced atoms or nano-clusters on the working electrode are shaken away by the vibration. Preferably, the produced atoms are immediately removed from the working electrode, thus no plating occurs on the surface.

The vibration, which continuously acts on the working electrode, should be strong enough to shake off the atoms or nano-clusters from the surface of the working electrode. On other hand, excessive vibration is not desired. It could be a sonic vibration or an ultrasonic vibration.

The ultrasound effect has been explored in sonoelectrochemical and sonochemical syntheses of various metallic nanoparticles or fine particles including Au, Ag, Cu, Zn and Fe. The sonoelectrochemical reduction has been characterized by an electrolysis cell including a power supply, cathode, anode and electrolyte solution. Sonochemical reduction is usually realized by a direct immersion of a high-intensity ultrasound titanium horn into the metal ion solution. The whole sonochemical process typically lasts for several hours. Usually alcohol molecules such as propanol are added for a higher yield of ultrasound-induced secondary reducing radicals. The particle size and particle formation efficiency is dependent on the presence, type and concentration of the alcohol. In these reactions, electrons from the external power supply and the ultrasound induced free radicals were attributed to be the reducing source in sonoelectrochemical and sonochemical reduction respectively, while ultrasound was speculated to be aiding in removing the electrodeposited particles on the sonocathode surface.

The sonoelectrochemical and sonochemical syntheses are featured by the ultrasonication, the intermitted operation with alternative electrochemical reaction and the ultrasonication, and the tip of the horn as the working area. A typical sonoelectrochemical formation of nanoscale metal and semiconductor powders was accomplished by applying an electric current pulse to nucleate the electrodeposits, followed by a burst of ultrasonic energy that removes the particles from the sonoelectrode (I. Haas, et al., J. Phys. Chem. B110, 16947-16952, 2006).

The ultrasonication, generally with a frequency larger than 20 kHz, was applied for two reasons: to generate enough cavitations for sonochemistry and to produce enough force that shakes off the nano-clusters on the cathode. The intermitted operation was intended to have electrochemical reduction at the cathode, to destroy the electrical double-layer of the electrolyte, and to remove the nano-cluster from the cathode. The key to the synthesis was electrodeposition. However, a burst of ultrasonication is necessary to prevent too much electrodeposition of electroplating. The same applies to the use of the tip of the horn as the working area, where the area that acts as the electrochemical reaction active area for electrodepostion, as the burst of ultrasonication had to be strong enough to remove the nano-cluster and to generate sonochemistry as stated in literatures (e.g. Jia et al., Powder Technology 176, 130-136, 2008).

In existing sonoelectrochemical synthesis, the sono-effect that produces cavitation of local high pressure and high temperature is regarded as an important factor for the chemical reaction. The high frequency of ultrasonication, the pulsed electricity and sonication and the use of the tip of the horn all were deemed as necessary for the formation of cavitation so as to produce sonochemistry and to remove nano-clusters from the working electrode. In short, all sonoelectrochemical syntheses of nanoparticles or fine particles were based on sonochemistry that was proposed by Reisse and co-workers (J. Reisse, H. Francois, J. Vandjzrcammen, et al., Electrochimica Acta, vol. 39, pp. 37-39, 1994).

Clearly, electroplating occurs in all existing sonoelectrochemical synthesis, where the plated nano-clusters were removed by the burst of ultrasonication. Depending upon the tendency of attachment of the nano-cluster to the cathode, a large amount of energy had to be used to generate a burst with enough strength that can remove the plated nano-cluster. Thus, the synthesis is not economic nor is scalable for mass production (Y. Kehelaers, J.-C. Delpllancke, J. Reisse, Chimia, vol. 54, pp. 48-50, 2000).

The fundamental of our proposed method is different from that of the above method: We have found for the first time that the electrochemical reaction can occur simultaneously with the ejection of the newly formed atoms/molecules, or nano-clusters at the working electrode. Preferably, electroplating could be avoided completely. The first aspect of the invention described above has demonstrated that mechanical rubbing could prevent plating. A suitable mechanical vibration could also avoid plating.

As long as the mechanical vibration can shake off the formed atoms/molecule at the working electrode, in our vibration-assisted synthesis system the vibration frequency can be any number. Furthermore, our system/method is distinctive from sonoelectrochemical method for other two more reasons: first our system runs with simultaneous electrolysis and vibration; and secondly, the effective reaction surface is the entire working electrode, which could have a solid or shell structure with a geometry of cylinder, or cone, or staged cylinder, or the combination of both, though a working electrode can have a horn like structure as that in sonoelectrochemical synthesis.

Preferably, the vibration produced by the generator has the same or close to the resonate frequency of the working electrode. Under sonication, the working electrode vibrates so as to shake off the atoms or the nano-cluster because of inertial force. Additionally, vibration produces pressure waves in solution, forming acoustic micro-streaming and possible acoustic cavitation. The acoustic micro-streaming can then enhance mass transfer at the working electrode-liquid interface by reducing the cation concentration gradient.

The largest advantage of our method is the scalability for large quantity production. This is because our method could be a continuous process, and the components of the synthesis system are scalable. The latter is due to the simple structure of the working electrode. The second advantage is its economy for two reasons: Our synthesis could work under the same condition as the industrial electroplating such as the same working electrolysis current as shown in our synthesis experiments; the mechanical rubbing or the mechanical vibration is designed to be suitable to shake off the atoms/molecules from the electrode. In contrast, the sonoelectrochemical method never worked under the same condition as the industrial electroplating, and excessive energy is wasted for producing the burst of sonication at the tip o the horn. The third advantage is its controllability: as long as a suitable mechanical vibration or rubbing is maintained, one can adjust the current, the cation concentration in the electrolyte, and the residence time (for the continuous mode of synthesis) to adjust the particle size and size distribution. However, it is difficult to control the synthesis process in sonoelectrochemical method, as it is already difficult to maintain an intermitted electrochemical reduction and a pulsed sonication that matches the electrochemical reaction condition, not to mention to adjust other parameters.

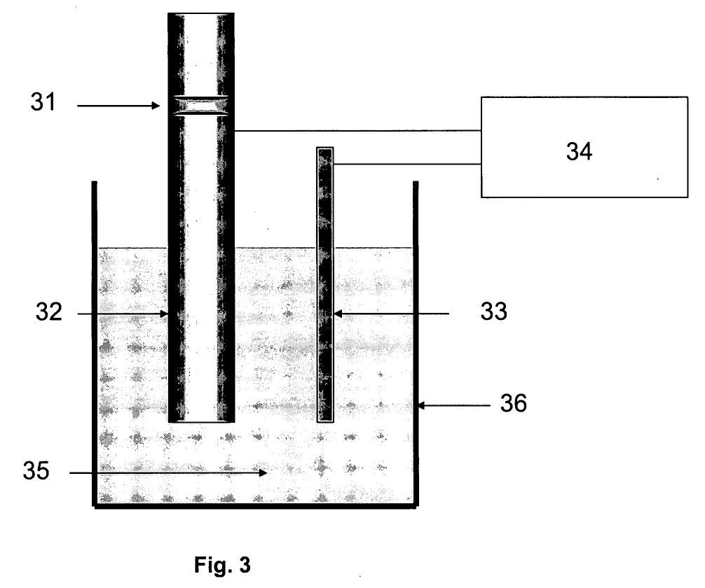

FIG. 3 shows a schematic setup for the vibration-assisted synthesis system. The piezoelectrics 31 produces vibration, which transduces to the working electrode 32. The working electrode 32 and counter electrode 33 are connected to the potentiostat 34. Both the electrodes and the electrolyte 35 are in the reactor 36.

### EXAMPLE 1

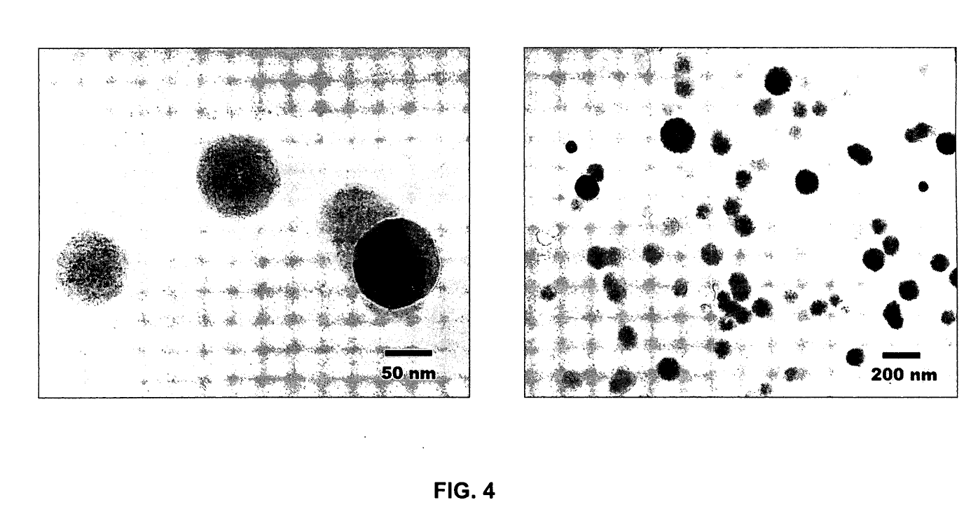

As an example of the synthesis strategy, copper sulfate pentahydrate (CuSO4 99.9+%, Alfa Aesar) is mixed with polyvinylpyrrolidone (PVP, weight-average molecular weight of 58K, Acros Organics) in deionized water at room temperature at various reported concentrations. A copper foil (0.5 mm thick, 50×200 mm, Alfa Aesar) is employed as the anode for the generation of copper nanoparticles or fine particles in the reactor. The CuSO4/PVP solution is put into the reaction vessel (500 ml in vessel). A titanium member with an active/reactive area of 8 cm², attached to a piezoelectric material, is used as the cathode. The piezoelectric material produces a frequency of 20 kHz. A voltage between 1.3 and 1.7 Volts is applied to the cathode and anode. A current of 1.5 A is applied between the anode and the cathode. FIG. 4 shows TEM images of synthesized Cu nanoparticles or fine particles. It is worthwhile to point out that the working electrolysis current is close to that used in industrial electrolysis for refining copper.

### EXAMPLE 2

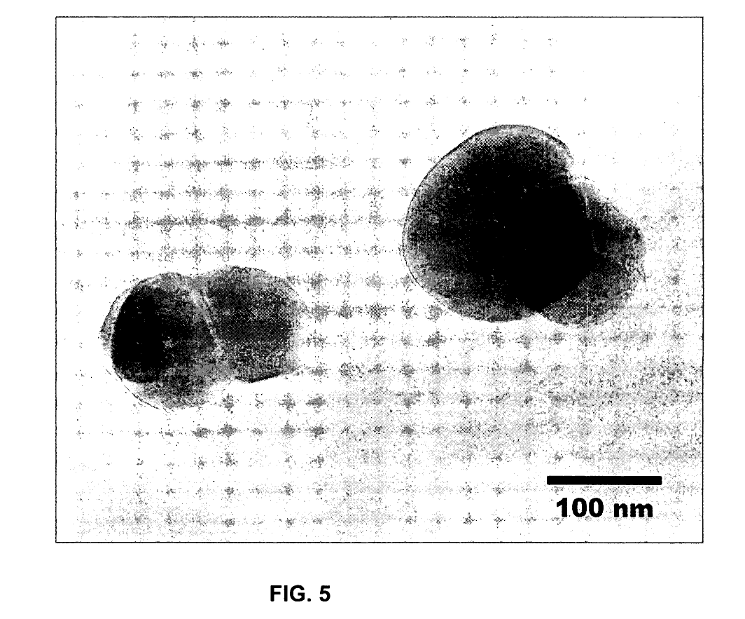

In application of nanoparticles or fine particles (nano-powder), sometimes the surfactant is not desirable. In this synthesis example, no surfactant is used. 100 g of copper sulfate pentahydrate (CuSO4 99.9+%, Alfa Aesar) is dissolved in 400 ml of deionized water at room temperature. A copper foil (0.5 mm thick, 50×200 mm, Alfa Aesar) is employed as the anode. A titanium member with an active/reactive area of 5 cm², attached to a piezoelectric material, is used as the cathode. The piezoelectric material produces a frequency of 20 kHz. A voltage of 1 Volt is applied to the cathode and anode. A current of 1-1.2 A is applied between the anode and the cathode. FIG. 5 shows TEM images of synthesized Cu nanoparticles or fine particles. Clearly, without adding surfactant, the particles are larger than that synthesized in Example 1 even though their synthesis conditions are close to each other.

### EXAMPLE 3

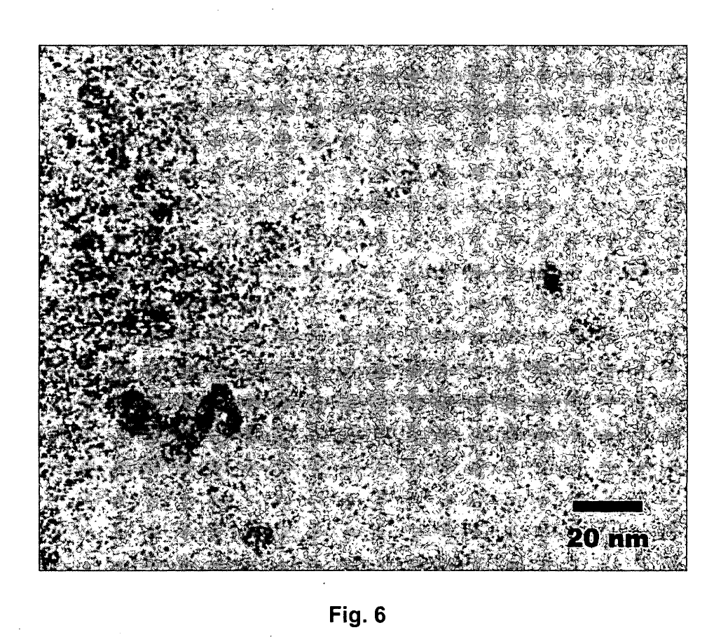

This synthesis example shows synthesis of iron nanoparticles or fine particles. In this synthesis example, no surfactant is used. 55.6 g of ferrous sulfate heptahydrate (FeSO4 99.9+%, Alfa Aesar) is dissolved in 200 ml of deionized water at room temperature. An iron foil (0.5 mm thick, 50×50 mm, Alfa Aesar) is employed as the anode. A titanium member with an active/reactive area of 8 cm², attached to a piezoelectric material, is used as the cathode. The piezoelectric material produces a frequency of 20 kHz. A voltage of 0.7 Volts is applied to the cathode and anode. A current of 0.09 A is applied and maintained during electrolysis. FIG. 6 shows TEM images of synthesized Fe nanoparticles or fine particles.

1. A method for making nanoparticles or fine particles, comprising:
in an electrolysis cell, a power (potentiostat) is supplied to an element that acts as a counter electrode, and another element that is working electrode; and
rubbing the working electrode to make nanoparticles or fine particles.

2. The method of claim 1, wherein the step of rubbing the working electrode includes rubbing a rubbing member against the working electrode, wherein at least one of the rubbing member and the working electrode is moving.

3. The method of claim 1, further comprising repeating the steps of claim 1 with a different material element to make core-shell like structured nanoparticles or fine particles.

4. The method of claim 1, the electrolysis cell contains two or more metallic components acting as anode to make intermetallic nanoparticles or fine particles.

5. The method of claim 1, further comprising adding a gas to the electrolyte solution to make nanoparticles or fine particles, and wherein the nanoparticles or fine particles are oxide nanoparticles or fine particles.

6. The method of claim 1, further comprising adding a surfactant to the electrolyte.

7. The method of claim 1, further comprising adding an antioxidant to the electrolyte.

8. The method of claim 1, the electrolyte may be a mixture solution containing two or more kinds of cations with elements required to form semiconductor compounds.

9. The method in claim 8, the CdSO₄/Na₂SeO₃ mixture solution may act as the electrolyte and some electrochemically inert material such as Pt acted as the counter electrode (anode).

10. The method in claim 1, the electrolyte may be a mixture solution containing the precursor monomer and the supporting electrolyte for making conducting nanoparticles or fine particles.

11. A method for making nanoparticles or fine particles, comprising:
in an electrolysis cell, a power (potentiostat) is supplied to an element that acts as a counter electrode, and another element that is working electrode; and
mechanically vibrating the working electrode to make nanoparticles or fine particles.

12. The method of claim 11, wherein the step of vibrating the working electrode includes vibrating the working electrode.

13. The method of claim 11, further comprising repeating the steps of claim 19 with a different material element to make core-shell like structured nanoparticles or fine particles.

14. The method of claim 11, the electrolysis cell contains two or more metallic components acting as anode to make intermetallic nanoparticles or fine particles.

15. The method of claim 11, further comprising adding a gas to the electrolyte solution to make nanoparticles or fine particles, and wherein the nanoparticles or fine particles are oxide nanoparticles or fine particles.

16. The method of claim 11, further comprising adding a surfactant to the electrolyte.

17. The method of claim 11, further comprising adding an antioxidant to the electrolyte.

18. The method of claim 11, the electrolyte may be a mixture solution containing two or more kinds of cations with elements required to form semiconductor compounds.

19. The method in claim 18, the CdSO₄/Na₂SeO₃ mixture solution may act as the electrolyte and some electrochemically inert material such as Pt acted as the counter electrode (anode).

20. The method in claim 11, the electrolyte may be a mixture solution containing the precursor monomer and the supporting electrolyte for making conducting nanoparticles or fine particles.
